(19) United States
(12) Patent Application Publication
(10) Pub. No.: US 2026/0156948 A1
(43) Pub. Date: Jun. 4, 2026

(54) INTEGRATED TRANSISTOR AND SILICON CONTROLLED RECTIFIER WITH NANOSHEET GATES

(71) Applicant: INTERNATIONAL BUSINESS MACHINES CORPORATION, ARMONK, NY (US)

(72) Inventors: Anindya Nath, Watervliet, NY (US); Robert Gauthier, Williston, VT (US); Anthony I-Chih Chou, Guilderland, NY (US); Masoud Zabihi, Schenectady, NY (US)

(21) Appl. No.: 18/966,007

(22) Filed: Dec. 2, 2024

(51) Int. Cl. H01L 21/02

(52) U.S. Cl. CPC H10D 89/713; H10D 30/501

(57) ABSTRACT

A semiconductor device includes a silicon controlled rectifier (SCR) including a P-type doped region and an N-type doped region, an N-well region, a P-well region adjacent to the N-well region, a set of shallow trench isolation (STI) below the P-type doped region and the N-type doped region and within the N-well region and the P-well region, and a transistor coupled to the SCR. The N-well region and the P-well region are located below the P-type doped region and the N-type doped region

### BACKGROUND

### Technical Field

The present disclosure generally relates to semiconductors, and more particularly, to integrated semiconductors and silicon-controlled rectifier with nanosheet gate structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a silicon controlled rectifier (SCR) including a P-type doped region and an N-type doped region, an N-well region, a P-well region adjacent to the N-well region, a set of shallow trench isolation (STI) below the P-type doped region and the N-type doped region and within the N-well region and the P-well region, and a transistor coupled to the SCR. The N-well region and the P-well region are located below the P-type doped region and the N-type doped region

In one embodiment, the semiconductor device includes a set of gate regions on opposite ends of the N-type doped region and the P-type doped region.

In one embodiment, the semiconductor device includes a substrate below the N-well region and the P-well region.

In one embodiment, each of the N-type doped region and the P-type doped region includes a plurality of nano-sheet channels between a corresponding doped region and a gate region.

In one embodiment, the plurality of nano-sheet channels includes alternative layers extended horizontally between the corresponding doped region and the gate region.

In one embodiment, the alternative layers include silicon.

In one embodiment, the transistor is a field-effect transistor (FET), and the FET and the SCR form a FET triggered SCR.

In one embodiment, the FET includes nano-sheet channels.

According to an embodiment, a method of fabricating a semiconductor device includes forming a silicon controlled rectifier (SCR) including forming a P-type doped region and an N-type doped region, forming an N-well region, forming a P-well region adjacent to the N-well region, forming a set of shallow trench isolation (STI) below the P-type doped region and the N-type doped region and within the N-well region and the P-well region, and forming a transistor coupled to the SCR. The N-well region and the P-well region are located below the P-type doped region and the N-type doped region;

In one embodiment, the method includes forming a set of gate regions on opposite ends of the N-type doped region and the P-type doped region.

In one embodiment, the method includes forming a substrate below the N-well region and the P-well region.

In one embodiment, forming each of the N-type doped region and the P-type doped region includes forming a plurality of nano-sheet channels between a corresponding doped region and a gate region.

In one embodiment, forming the plurality of nano-sheet channels includes extending alternative layers horizontally between the corresponding doped region and the gate region.

In one embodiment, the alternative layers include silicon.

In one embodiment, the transistor is a field-effect transistor (FET), and the FET and the SCR form a FET triggered SCR.

In one embodiment, the FET includes nano-sheet channels.

According to an embodiment, a semiconductor device includes a silicon controlled rectifier (SCR), a first transistor coupled to the SCR on a first end of the SCR, and a second transistor coupled to the SCR on a second end of the SCR, wherein the first transistor is a p-field effect transistor (pFET) and the second transistor is an nFET.

In an embodiment, the SCR includes a P-type doped region and an N-type doped region, an N-well region, a P-well region adjacent to the N-well region, wherein the N-well region and the P-well region are located below the P-type doped region and the N-type doped region, a set of shallow trench isolation (STI) below the P-type doped region and the N-type doped region and within the N-well region and the P-well region.

In one embodiment, the semiconductor device includes a set of gate regions on opposite ends of the N-type doped region and the P-type doped region, and a substrate below the N-well region and the P-well region.

In one embodiment, each of the N-type doped region and the P-type doped region includes a plurality of nano-sheet channels between a corresponding doped region and a gate region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate schematically an ESD device operation during the normal circuit operation voltage range, ESD operating window during an ESD event, and the failure region.

FIGS. 2A-2B illustrate cross-sectional views of a conventional diode/bipolar string triggered electrostatic discharge device and its circuitry.

FIGS. 2C-2E illustrate circuitry of the semiconductor device shown in FIG. 2A.

FIG. 2F is an I-V graph of the semiconductor device shown in FIG. 2A.

FIG. 3A illustrates a semiconductor device with one transistor coupled to a silicon controlled rectifier, in accordance with an embodiment.

FIG. 3B illustrates a schematic view of the semiconductor device shown in FIG. 3A.

FIG. 4A illustrates a semiconductor device with two transistors coupled to a silicon controlled rectifier, in accordance with an embodiment.

FIG. 4B illustrates a schematic view of the semiconductor device shown in FIG. 4A.

FIG. 5 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

In foundry technology, developing a complete portfolio of electrostatic discharge (ESD) protection devices is important to support the diverse types of input/output (I/O) configurations used in advanced semiconductor designs. ESD protection devices can safeguard sensitive electronic components against high-voltage spikes and unintended electrical discharges, which can occur during manufacturing, assembly, or end-use handling. As technology scales down to nodes such as 2 nm and below, achieving robust ESD protection becomes increasingly challenging due to the ultra-small geometries and reduced breakdown voltages of modern transistors.

Key types of ESD devices for a comprehensive protection solution include NPNP or PNPN structures, which are typically implemented as thyristors or silicon-controlled rectifiers (SCRs). These devices, characterized by their four-layer structure of alternating P- and N-type regions, can absorb and divert large amounts of charge during an ESD event. The thyristor, in particular, operates as a controlled switch with two stable states, enabling it to withstand high-voltage transients without triggering during normal circuit operation. An SCR, on the other hand, offers even more robust ESD protection, as it can latch into a low-resistance state when triggered, allowing it to handle higher current levels than typical ESD diodes or resistive networks. However, as scaling progresses to the 2 nm node and below, there are disadvantages in current technology such as the breakdown voltage, leakage characteristics, and latch-up immunity of the devices.

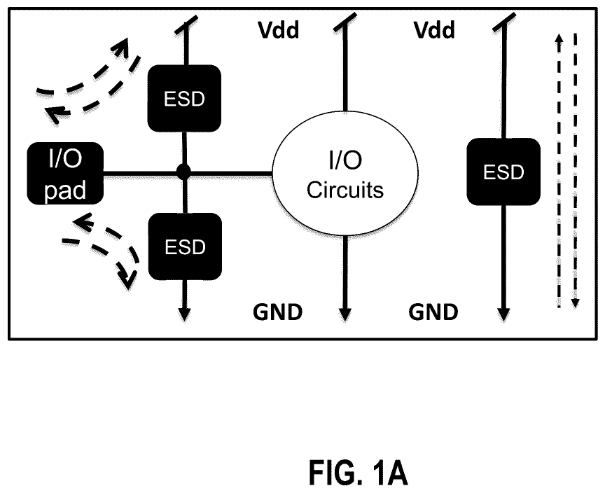

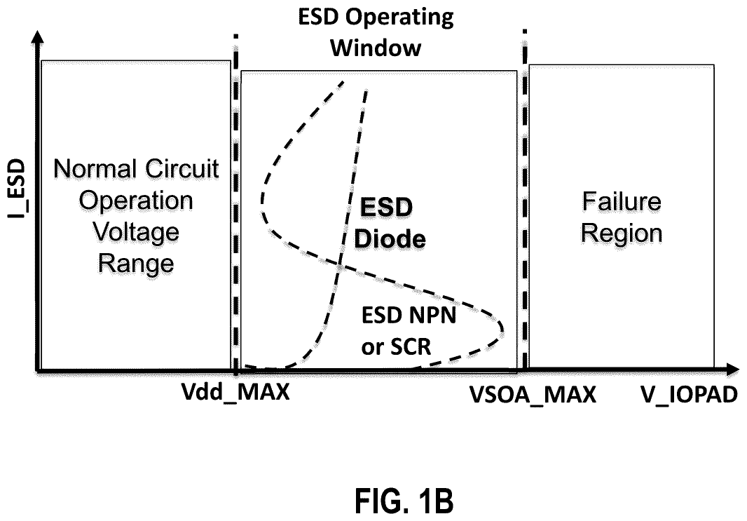

FIGS. 1A-1B illustrate schematically an ESD device operation during the normal circuit operation voltage range, ESD operating window during an ESD event, and the failure region.

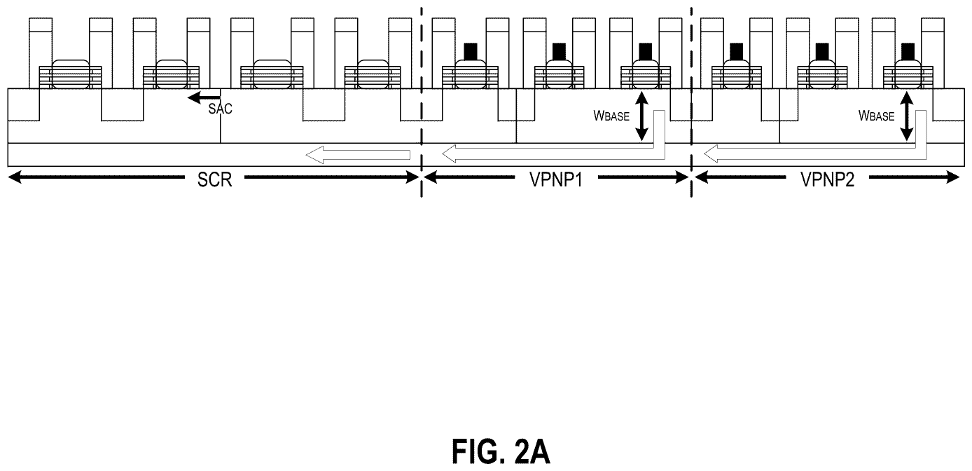

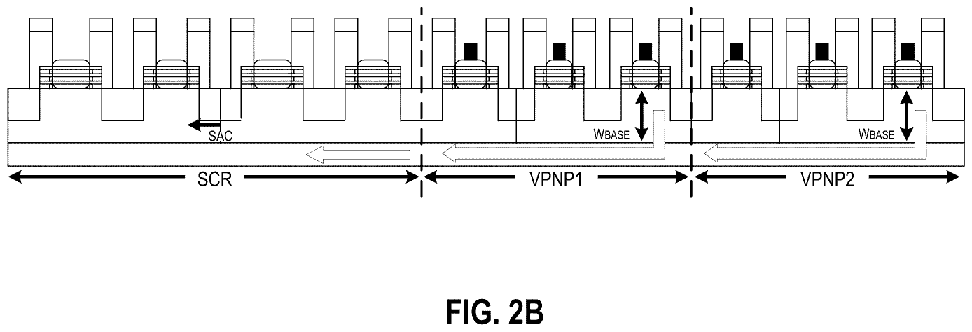

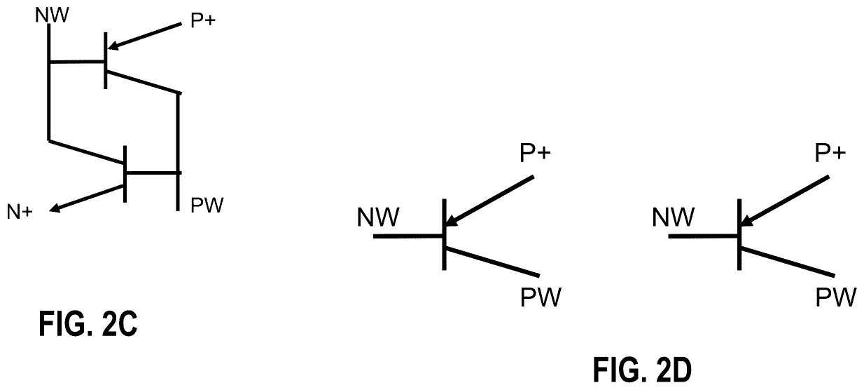

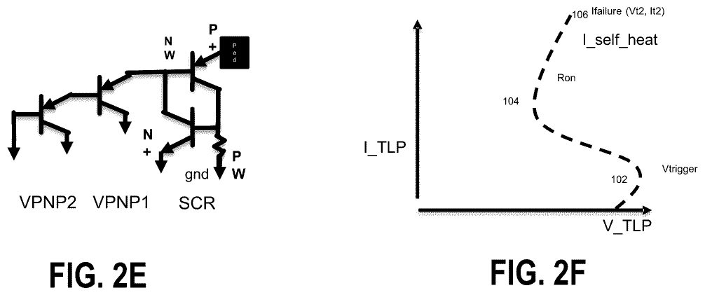

FIGS. 2A-2F illustrate a conventional diode/bipolar string triggered electrostatic discharge device and its circuitry. The device shown in FIG. 2B includes STI below the base, while the device shown in FIG. 2A lacks such STI below the base. A diode/bipolar string-triggered electrostatic discharge (ESD) protection device is designed to safeguard sensitive electronic components from voltage spikes due to ESD events by creating a controlled discharge path that diverts excessive current safely away from protected circuitry. Under normal operating conditions, the ESD protection device remains in a high-impedance, non-conductive state, isolating itself from the circuit to prevent interference with the device's usual functionality. The diode or bipolar junction transistor (BJT) string is reverse-biased or configured in such a way that it does not conduct any significant current, e.g., 1 micro-Ampere or less, under standard voltage levels, ensuring that the protection device remains inactive.

The I-V graph of a diode/bipolar string triggered ESD protection device typically exhibits distinct regions that correspond to its behavior under varying voltage and current conditions. At the pre-trigger current region (point 102), the device is in its off state, with only a small leakage current flowing through it. This is typically a low-current, high-resistance state. The voltage increases with minimal current flow until it reaches the trigger voltage. At the snap-back region (from point 102 to point 104), as the voltage reaches the trigger threshold, the device transitions into conduction mode. This region is characterized by negative resistance, where an increase in current results in a decrease in voltage across the device. This snap-back effect occurs due to the activation of the bipolar transistor within the structure, which leads to a significant reduction in the device's resistance and allows current to flow more freely. At the high current conduction region (from point 104 to point 106), the device conducts high levels of current as it clamping the voltage at a safe level to protect downstream circuitry. The onset of self-heating becomes evident as the device handles high currents, which may result in a slight upward curvature in the I-V characteristic due to thermal effects increasing the resistance slightly.

When an ESD event occurs, it introduces a rapid and high-voltage spike, which can be (by way of example and not limitation) between 2,000 to 25,000 volts and at rise times of 0.7 to 10 nanosecond (ns) at an input/output (I/O) pin or power rail, often originating from a charged object such as a human body or another conductive item. This voltage spike, significantly higher than the circuit's operating range, is sensed by the ESD device. The protection mechanism in the diode or BJT string is designed with a breakdown threshold slightly above the normal operating voltage yet below levels that would be damaging to the circuitry. As the ESD voltage climbs and reaches this breakdown threshold, the diodes or BJTs in the string enter a breakdown mode, creating a conductive path for the transient current.

In a diode string, each diode, e.g., VPNP1 and VPNP2, undergoes reverse breakdown as the ESD voltage exceeds the threshold, providing a low-resistance discharge path for the ESD current. Alternatively, in a bipolar string, each transistor becomes forward biased under the ESD voltage, behaving like a switch that enables a continuous current path from the ESD event to ground. The bipolar junction transistors are designed to “turn on” when the ESD voltage rises above the safe operating threshold, allowing them to conduct high currents briefly, which safely dissipates the excess charge. This controlled conduction prevents the high voltage from reaching sensitive areas in the circuit.

As the breakdown occurs, the ESD device provides a low-resistance path through the diode or BJT string, effectively shunting the excessive ESD current away from the sensitive parts of the circuit to a ground or designated power rail. In a diode string, each diode breakdown stage sequentially reduces the resistance, directing the current through the device without allowing high voltage to interfere with the protected circuit. In a bipolar string, each forward-biased transistor acts collectively to create a low-resistance path that can handle substantial current flow (e.g., 1-12 amps during peak currents) for the brief duration of the ESD event.

Once the ESD event has dissipated and the voltage level returns to its normal range, the diode or BJT string exits its breakdown or forward-biased state. The device then reverts to a high-impedance mode, disconnecting from the circuit and resuming its inactive state. With the high impedance restored, the ESD protection device does not influence normal circuit operation and is now ready to protect against any future ESD events without impacting the regular functionality of the protected circuitry.

Diode and bipolar string ESD protection devices are particularly effective in providing targeted protection. Their ability to remain inactive under normal operating conditions while offering a robust, predictable discharge path during an ESD event makes them well-suited for integration into advanced transistor technologies. Furthermore, bipolar transistors are particularly advantageous in compact designs, as they can handle high currents in a small footprint, an important factor in applications where space constraints and high-performance requirements are both priorities. Through this mechanism, the diode or BJT string ESD device efficiently manages ESD events by diverting harmful currents and allowing the circuit to maintain integrity and reliability despite unexpected voltage surges.

For advanced 2 nm technology and below, incorporating a low-voltage trigger SCR is also useful to support the lower operating voltages and faster switching speeds of nanoscale devices. Disclosed is a low-voltage trigger SCR, which can include SCR integrated with one or more transistors, designed to initiate protection at voltages compatible with ultra-scaled transistors, where traditional ESD devices with higher trigger voltages may be insufficient to prevent damage. By lowering the trigger voltage, the SCR can provide effective ESD protection that activates before the core circuitry is exposed to harmful voltage levels. Such benefits are achieved by utilizing advanced materials and precise control over doping levels and junction depths to maintain a consistent trigger point while reducing (e.g., minimizing) leakage and maintaining high immunity to latch-up.

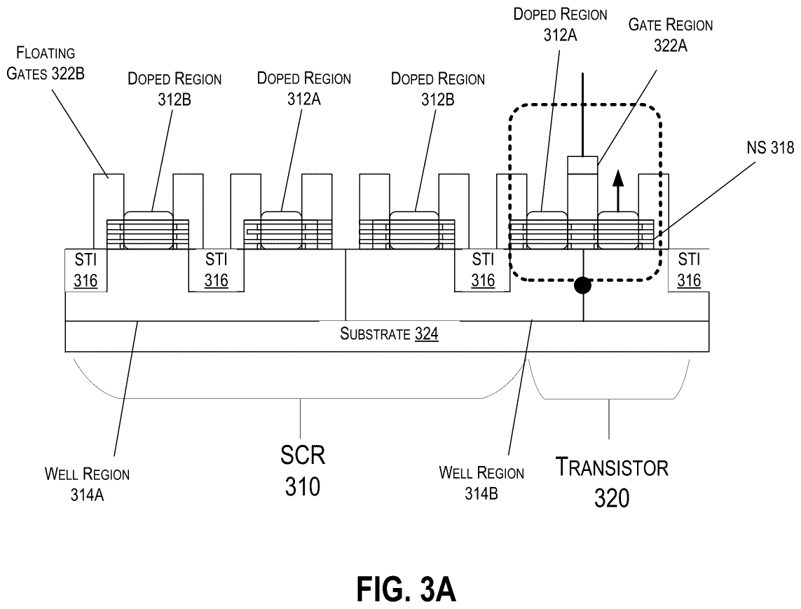

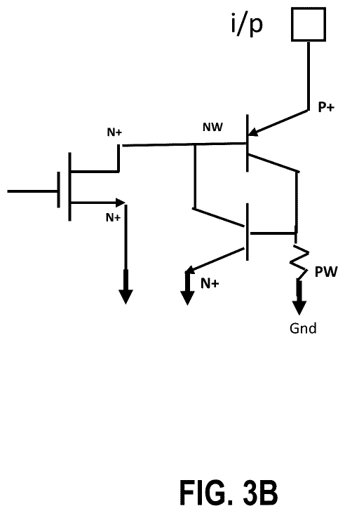

Accordingly, the teachings herein provide methods and systems of integrated semiconductors and silicon controlled rectifier with nanosheet gate structure. The techniques described herein may be implemented in a number of ways. Example implementations are provided below with reference to the following figures. Reference now is made to FIGS. 3A-3B, which provides a cross-section view and a schematic view, respectively, of a semiconductor device, consistent with illustrative embodiments. FIG. 3A illustrates a semiconductor device with one transistor coupled to a silicon controlled rectifier in series, in accordance with an embodiment. FIG. 3B illustrates exemplary circuitry (i.e., schematic view) of the semiconductor device as shown in FIG. 3A. It should be noted that, The FETs can be integrated to the NW and PW of the SCRs, respectively. In some embodiment, an nFET is coupled between the NW and ground, and in some embodiments, a pFET is coupled between the PW and ground. In some embodiments, both transistors could be controlled by power on reset signal.

The semiconductor device can be structured with a silicon-controlled rectifier (SCR) and a transistor in a specific arrangement that provides control over current flow and enables both rectification and switching functionality. Each element of the semiconductor device contributes uniquely to its performance and stability. The SCR 310 can include a P-type doped region 312B and an N-type doped region 312A, which serve as regions where charge carriers, such as electrons and holes, are concentrated. The P-type doped region 312B includes a high concentration of positively charged carriers (holes), while the N-type doped region 312A is rich in negatively charged carriers (electrons). Such a configuration allows for a controlled flow of current between the two regions under specific conditions, contributing to the SCR's ability to regulate the discharge of excess current when activated.

Each of the N-type doped region 312A and the P-type doped region 312B can be created by doping with a type P dopant, which introduces an excess of positive charge carriers (holes), or with a type N dopant, which introduces an excess of negative charge carriers (electrons). A P-type doped region and an N-type doped region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

The SCR 310 can be configured with an N-well region 314B and a P-well region 314A, both of which are foundational layers located beneath the P-type doped region 312B and the N-type doped region 312A. The N-well region 314B provides a stable base with a concentration of electrons, while the P-well region 314A contains a concentration of holes. The placement of the N-well region 314B and the P-well region 314A directly below the P-type doped region 312B and the N-type doped region 312A enhances the charge control within the SCR 310. The layered configuration between the N-well region 314B and the P-well region 314A facilitates regulation of current flow, allowing the SCR 310 to handle high current levels without unintended activation during regular operation.

In addition to the wells, a set of shallow trench isolation structures, STI 316, is located within both the N-well region 314B and the P-well region 314A, positioned just below the P-type doped region 312B and the N-type doped region 312A. The STI 316 can be physical isolation structures etched into the semiconductor material, then filled with an insulating material to electrically separate adjacent components. The STI 316 can effectively limit unwanted current paths between regions, ensuring that charge carriers remain confined within their respective paths. By isolating the P-type doped region 312B and the N-type doped region 312A within the N-well region 3114A and the P-well region 314A, the STI 316 can help prevent electrical leakage and interference from neighboring areas, thereby preserving the SCR's functionality and reliability.

The transistor 320 in the semiconductor device can be coupled in series with the SCR 310, working together to provide an integrated current regulation system. The coupling allows the transistor 320 to assist in triggering the SCR's activation under controlled conditions. The transistor's role can include managing the current entering the SCR 310, contributing to the overall stability and control of the semiconductor device. In some embodiments, the transistor 320 is configured as a field-effect transistor (FET).

When the transistor 320 is a FET, the semiconductor device forms a FET-triggered SCR, where the FET serves as the primary component that initiates the SCR's operation. Such a configuration allows for efficient triggering of the SCR 310, enhancing the semiconductor device's response time and reliability under high-current events. In particular, when the FET is used as a triggering mechanism, it provides a reliable means of switching on the SCR 310 when the current or voltage level exceeds a certain threshold, thereby protecting sensitive circuitry from sudden current surges. In some embodiments, the transistor 320 can include nano-sheet, NS 318, which are thin, horizontally oriented conductive sheets that act as channels within the FET structure. These NS 318 can increase the transistor's switching capabilities, allowing the semiconductor device to achieve faster response times while operating at lower voltages. a transistor coupled in-between the N-well region and the P-well region and configured to provide an alternate path before the SCR is turned on.

In some embodiments, gate regions 322A is positioned at opposite ends of the P-type doped region 312B and the N-type doped region 312A The gate regions 322A provide control over the flow of charge carriers within the SCR 310 by applying an external voltage to modulate the conductivity between the doped regions. The positioning of the gate regions 322A can allow them to effectively control the current paths in the SCR 310, enabling switching between conductive and non-conductive states. The semiconductor device can further include dummy gates, e.g., floating gates 322B. In some embodiments, a set of gate regions are located on two ends of the N-type doped region and the P-type doped region.

In some embodiments, the gate regions 322A are coupled with the plurality of nano-sheet channels, e.g., NS 318, positioned between each doped region and its respective gate region. These NS 318 can enhance the ability to control current flow within the doped regions, providing improved switching capabilities and better modulation of the SCR's conductivity. The NS 318 can act as intermediate control elements, working in tandem with the primary gate regions to fine-tune the response of the P-type doped region 312B and the N-type doped region 312A.

Each of the P-type doped region 312B and the N-type doped region 312A can include a plurality of nano-sheet channels, e.g., NS 318, which are positioned between the respective doped regions and their corresponding gate regions. The nano-sheet channels are composed of ultra-thin layers that facilitate precise control over the flow of charge carriers. Positioned horizontally, the nano-sheet channels provide additional structural support and enhance the semiconductor device's responsiveness by reducing the time required to switch between states. In some embodiments, the nano-sheet channels include alternative layers composed of silicon. The NS 318 can conduct triggering current to turn-on the SCR. In some embodiments, the gate regions 322A are controlled by control signal, e.g., power on reset (POR).

The semiconductor device can include a substrate 324 positioned below the N-well region 314B and the P-well region 314A, which serves as the foundation upon which all other elements are built. The substrate 324 provides structural support for the semiconductor device and acts as a platform for the SCR 310, the transistor 320, and associated elements. The substrate 324 can be lightly doped to create a stable, electrically neutral base that prevents unwanted interactions between the semiconductor device and the surrounding material. By providing a solid foundation, the substrate 324 can help maintain the alignment and positioning of the N-well region 314B, the P-well region 314A and other regions within the semiconductor device.

In some embodiments, it will be understood that other types of substrates, other than silicon, may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

The semiconductor device can be fabricated using nano-sheet, or nano-plane, technology, which is a process technology enabling control over device structures at the nanoscale. The epitaxial junctions, e.g., the P-type doped region 312B and N-type doped region 312A, can be formed and bounded by gate regions 322A. The epitaxial junctions are grown as thin, high-quality semiconductor layers with specific doping profiles to create P-type and N-type regions. The epitaxial growth process allows for tight control over the composition and thickness of the junctions, ensuring a uniform and defect-free layer that is important for achieving consistent electrical characteristics across the semiconductor device. The gates surrounding these junctions act as control elements, allowing for precise modulation of current flow through the epi regions, which is crucial in high-frequency or high-power applications.

Both P+ (highly doped P-type) and N+ (highly doped N-type) epitaxial junctions are established within the semiconductor device structure. Such junctions provide regions of high carrier concentration, enhancing conductivity and supporting efficient electron and hole flow within the device. In some embodiments, a P+/N-well/P-well/N+ silicon-controlled rectifier (SCR) or thyristor structure is formed within the semiconductor device. The SCR includes layers of alternating P-type and N-type regions, enabling it to function as a controlled switch that can conduct high current once triggered. The P+/N-well/P-well/N+ configuration creates a four-layered structure with inherent current-limiting and latching characteristics. When activated, this SCR can conduct a large current between its anode and cathode, making it suitable for use in applications that require robust protection against sudden surges, such as ESD protection or power control circuits. While the figures show that the SCR 310 is integrated with an nFET in series to form a FET-triggered SCR, it should be noted that the SCR can be made in such a way that can be integrated with a pFET in series as well.

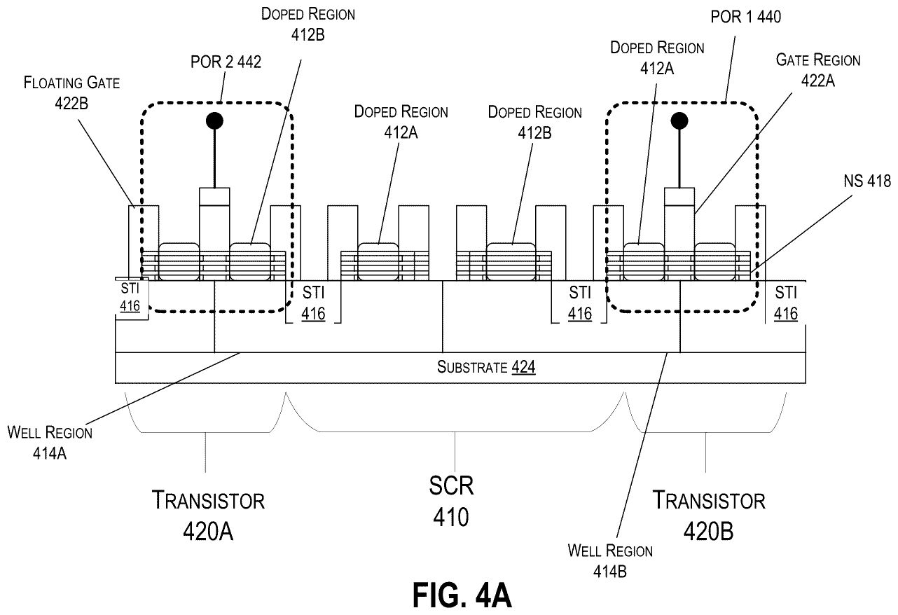

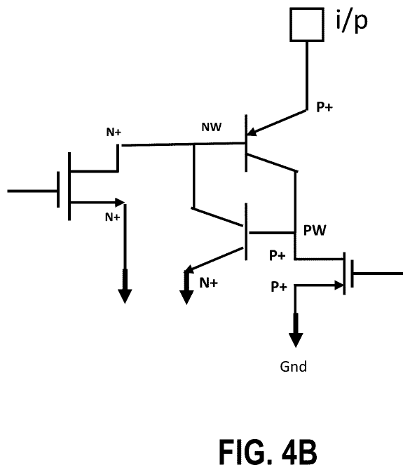

Reference now is made to FIGS. 4A-4B, which provides a schematic view of a semiconductor device, consistent with illustrative embodiments. FIG. 4A illustrates a semiconductor device with two transistors 420A and 420B coupled to a silicon-controlled rectifier in series, in accordance with an embodiment. FIG. 4B illustrates exemplary circuitry of the semiconductor device as shown in FIG. 4A.

In some embodiments, the semiconductor device is fabricated using advanced nano-sheet, or nano-plane, technology, which allows for control over ultra-thin layers of semiconductor material, optimizing the device for high-performance applications that demand efficient current control, fast switching speeds, and reduced power consumption. Within the nano-sheet technology, epitaxial junctions, e.g., N-type doped regions 412A and P-type doped regions 412B, are formed and bounded by gate regions 422. The epitaxial growth process allows for the formation of high-quality P-type and N-type semiconductor regions with controlled thickness and doping levels. The epitaxial layers, formed through deposition processes that ensure uniformity and reduce (e.g., minimize) defects, provide regions where electron and hole movement can be modulated. The gate regions 422 surrounding the epitaxial junctions act as control elements, allowing the semiconductor device to fine-tune current flow across the junctions with high accuracy, which helps managing the operation of the semiconductor device under varying voltage conditions.

The semiconductor device includes both P+ and N+ epitaxial junctions. The P+ region, highly doped with P-type impurities, creates a hole-rich environment, while the N+ region, heavily doped with N-type impurities, provides an electron-rich environment. The P+ and N+ regions form the active areas within the semiconductor device, enabling efficient electron and hole flow under controlled conditions. By establishing regions with high concentrations of charge carriers, the P+ and N+ epitaxial junctions enhance the semiconductor device's ability to respond rapidly to changes in applied voltage, supporting high-speed and high-frequency operation.

The semiconductor device can incorporate N-well region 414A and P-well region 414B, which are formed to act as foundational layers for the P+ and N+ epitaxial junctions. The N-well region 414A is lightly doped with N-type impurities, creating a stable electron-rich foundation, while the P-well region 414B is doped with P-type impurities, establishing a stable hole-rich base. The well regions provide a controlled environment where the doped regions can interact without interference, supporting isolation and stability within the semiconductor device. The N-well region 414A and the P-well region 414B can establish well-defined zones of complementary conductivity, which enhances the device's overall performance in applications requiring accurate control over electron and hole movement. In some embodiments, the gate regions 422A, 422B are controlled by control signal, e.g., power on reset (POR 1 440 and POR 2 442).

In some embodiments, an SCR, or thyristor, is formed within the semiconductor device using a P+/N-well/P-well/N+ configuration. In some embodiments, the N-well region 414A of the SCR 410 is integrated with an nFET in series to form a FET-triggered SCR. In this configuration, the nFET acts as the initial trigger mechanism for the SCR 410, providing a pathway for current to flow and initiate the SCR's conductive state under controlled conditions. The nFET serves as an efficient and responsive switching element that activates the SCR 410 when certain voltage thresholds are reached. When the gate voltage of the nFET reaches a designated level, it allows current to flow through the N-well region 414A of the SCR 410, triggering it to enter a low-resistance state and conduct a larger current. This FET-triggered SCR provides responsive solution for applications requiring precise control over the SCR's activation, such as ESD protection or current-limiting circuits.

Additionally, the P-well region 414B of the SCR 410 is integrated with a pFET in series, creating a dual-FET triggered SCR. In this arrangement, the pFET is coupled with the P-well region 414B and acts as a second control point for activating the SCR 410. The integration of the pFET with the SCR 410 provides an additional layer of control, allowing the semiconductor device to respond selectively based on the polarity of the voltage applied to the pFET's gate. When a threshold voltage is applied to the gate of the pFET, it enables current to flow through the P-well region 414B, triggering the SCR 410 under specific conditions. The dual-FET configuration allows the SCR 410 to be triggered by either the nFET or pFET, providing a versatile activation mechanism that can respond to both positive and negative voltage event. The semiconductor device can further include the substrate 424, STI 416, and NS 418.

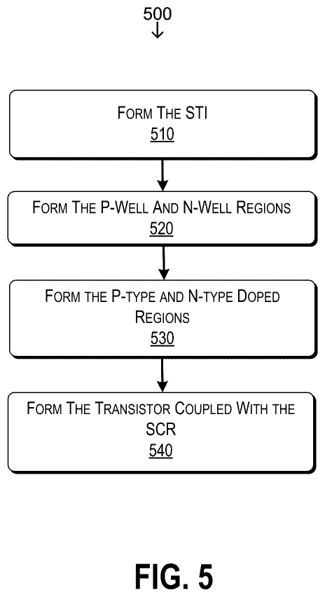

FIG. 5 illustrates a block diagram of a method 500 for forming the semiconductor device, in accordance with some embodiments. As shown by block 510, STI is formed.

As shown by block 520, a P-well region and an N-well region are formed.

As shown by block 530, P-type doped region and the N-type doped regions are formed.

As shown by block 540, a transistor formed coupled to the SCR in series.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a silicon controlled rectifier (SCR) comprising:
a P-type doped region and an N-type doped region;
an N-well region;
a P-well region adjacent to the N-well region, wherein the N-well region and the P-well region are located below the P-type doped region and the N-type doped region; and
a set of shallow trench isolation (STI) below the P-type doped region and the N-type doped region and within the N-well region and the P-well region; and
a transistor coupled in-between the N-well region and the P-well region and configured to provide an alternate path before the SCR is turned on.

2. The semiconductor device of claim 1, further comprising a set of gate regions on two ends of the N-type doped region and the P-type doped region.

3. The semiconductor device of claim 1, further comprising a substrate below the N-well region and the P-well region.

4. The semiconductor device of claim 1, wherein each of the N-type doped region and the P-type doped region further comprises a plurality of nano-sheet channels between a corresponding doped region and a gate region.

5. The semiconductor device of claim 4, wherein the plurality of nano-sheet channels comprises alternative layers extended horizontally between the corresponding doped region and the gate region.

6. The semiconductor device of claim 5, wherein the alternative layers include silicon.

7. The semiconductor device of claim 1, wherein the transistor is a field-effect transistor (FET), and wherein the FET and the SCR form a FET triggered SCR.

8. The semiconductor device of claim 7, wherein the FET includes nano-sheet channels.

9. A method of fabricating a semiconductor device, the method comprising:
forming a silicon controlled rectifier (SCR) comprising:
forming a set of shallow trench isolation (STI);
forming an N-well region;
forming a P-well region adjacent to the N-well region; and
forming a P-type doped region and an N-type doped region; and
forming a transistor coupled to the SCR,
wherein:
the N-well region and the P-well region are located below the P-type doped region and the N-type doped region; and
the set of STI is located below the P-type doped region and the N-type doped region and within the N-well region and the P-well region.

10. The method of claim 9, further comprising forming a set of gate regions on opposite ends of the N-type doped region and the P-type doped region.

11. The method of claim 9, further comprising forming a substrate below the N-well region and the P-well region.

12. The method of claim 9, wherein forming each of the N-type doped region and the P-type doped region further comprises forming a plurality of nano-sheet channels between a corresponding doped region and a gate region.

13. The method of claim 12, wherein forming the plurality of nano-sheet channels comprises extending alternative layers horizontally between the corresponding doped region and the gate region.

14. The method of claim 13, wherein the alternative layers include silicon.

15. The method of claim 9, wherein the transistor is a field-effect transistor (FET), and wherein the FET and the SCR form a FET triggered SCR.

16. The method of claim 15, wherein the FET includes nano-sheet channels.

17. A semiconductor device, comprising:
a silicon controlled rectifier (SCR);
a first transistor coupled in-between an N-well region and a P-well region; and
a second transistor coupled to the SCR with a second end of the SCR,
wherein the first transistor is a p-field effect transistor (pFET) and the second transistor is an nFET.

18. The semiconductor device of claim 17, wherein the SCR comprises:
a P-type doped region and an N-type doped region;
an N-well region;
a P-well region adjacent to the N-well region, wherein the N-well region and the P-well region are located below the P-type doped region and the N-type doped region; and
a set of shallow trench isolation (STI) below the P-type doped region and the N-type doped region and within the N-well region and the P-well region.

19. The semiconductor device of claim 18, further comprising:
a set of gate regions on opposite ends of the N-type doped region and the P-type doped region; and
a substrate below the N-well region and the P-well region.

20. The semiconductor device of claim 18, wherein each of the N-type doped region and the P-type doped region further comprises a plurality of nano-sheet channels between a corresponding doped region and a gate region.
